(19) United States
(12) Patent Application Publication
(10) Pub. No.: US 2022/0115285 A1
(43) Pub. Date: Apr. 14, 2022

(54) ENCAPSULATION MATERIAL, LAMINATED SHEET, CURED PRODUCT, SEMICONDUCTOR DEVICE, AND METHOD FOR FABRICATING SEMICONDUCTOR DEVICE

(71) Applicant: Panasonic Intellectual Property Management Co., Ltd., Osaka (JP)

(72) Inventors: Kazunari TANAKA, Osaka (JP); Shigeru YAMATSU, Mie (JP)

(73) Assignee: Panasonic Intellectual Property Management Co., Ltd., Osaka (JP)

(21) Appl. No.: 17/431,207

(22) PCT Filed: Feb. 6, 2020
(86) PCT No.: PCT/JP2020/004656

§ 371 Date: Aug. 16, 2021

(30) Foreign Application Priority Data
Feb. 21, 2019 (JP) 2019-029918

(51) Int. Cl. H01L 23/29; C09J 7/30; C09J 135/02; H01L 23/00; H01L 23/31; H01L 21/48; H01L 21/56

(52) U.S. Cl. CPC H01L 23/295; H01L 2924/18161; C09J 135/02; H01L 24/16; H01L 23/3185; H01L 21/4853; H01L 21/563; C09J 2467/006; C09J 2433/00; C09J 2471/00; H01L 2224/16227; H01L 2924/0635; H01L 2924/067; H01L 2924/0685; C09J 7/30

(57) ABSTRACT

An encapsulation material is used to fill a gap between a base member and a semiconductor chip to be bonded onto the base member. The encapsulation material has a reaction start temperature of 160° C. or less. A total content of components volatilized from the encapsulation material when the encapsulation material is heated to at least one temperature falling within a range from 100° C. to 170° C. is 0.5% by mass or less of the entire encapsulation material.

### TECHNICAL FIELD

The present invention generally relates to an encapsulation material, a laminated sheet, a cured product, a semiconductor device, and a method for fabricating the semiconductor device. More particularly, the present invention relates to an encapsulation material suitable for filling the gap between a base member and a semiconductor chip, a laminated sheet including the encapsulation material, a cured product of the encapsulation material, a semiconductor device including an encapsulant made of the cured product, and a method for fabricating a semiconductor device including the encapsulant.

### BACKGROUND ART

Patent Literature 1, for example, teaches that when a semiconductor device is fabricated by mounting a semiconductor chip on a substrate, solder in bump electrodes melts to connect the bump electrodes to conductor wiring on the substrate and a resin composition cures to form an encapsulant. More specifically, Patent Literature 1 teaches laying a sheet of a resin composition over the semiconductor chip, picking up the semiconductor chip with a bonding head, arranging the semiconductor chip in this state on the substrate, and then heating the bonding head, thereby heating the resin composition and the bump electrodes.

### CITATION LIST

### Patent Literature

Patent Literature 1: JP 2011-140617 A

### SUMMARY OF INVENTION

An object of the present invention is to provide an encapsulation material which reduces the chances of creating voids even if an encapsulant is formed after the encapsulation material, arranged to fill the gap between a base member and a semiconductor chip, has been heated and molded for a relatively short time at a relatively low temperature.

Another object of the present invention is to provide a laminated sheet made from the encapsulation material, a cured product of the encapsulation material, a semiconductor device including an encapsulant made of the cured product, and a method for fabricating such a semiconductor device.

An encapsulation material according to an aspect of the present invention is used to fill a gap between a base member and a semiconductor chip to be bonded onto the base member. The encapsulation material has a reaction start temperature of 160° C. or less. A total content of components volatilized from the encapsulation material when the encapsulation material is heated to at least one temperature falling within a range from 100° C. to 170° C. is 0.5% by mass or less of the entire encapsulation material.

A laminated sheet according to another aspect of the present invention includes the encapsulation material described above and a supporting sheet supporting the encapsulation material thereon.

A cured product according to still another aspect of the present invention is obtained by thermally curing the encapsulation material described above.

A semiconductor device according to yet another aspect of the present invention includes: a base member; a semiconductor chip bonded facedown onto the base member; and an encapsulant filling a gap between the base member and the semiconductor chip. The encapsulant is made of the encapsulation material described above.

A method for fabricating a semiconductor device according to yet another aspect of the present invention includes: providing a semiconductor chip including a bump electrode, with the encapsulation material interposed between the bump electrode and a surface having conductor wiring of a base member, such that the conductor wiring faces the bump electrode; and curing the encapsulation material and electrically connecting the conductor wiring and the bump electrode together by applying ultrasonic vibrations to the encapsulation material while heating the encapsulation material.

### BRIEF DESCRIPTION OF DRAWINGS

FIG. 1A is a schematic cross-sectional view illustrating a semiconductor device according to an exemplary embodiment of the present invention;

FIG. 1B is a schematic cross-sectional view illustrating a semiconductor device according to another exemplary embodiment of the present invention;

FIG. 2 is a schematic cross-sectional view illustrating a laminated sheet according to an exemplary embodiment of the present invention; and

FIGS. 3A-3D are schematic cross-sectional views illustrating respective process steps of bonding a semiconductor chip onto a base member according to an exemplary embodiment of the present invention.

### DESCRIPTION OF EMBODIMENTS

### 1. Overview

First of all, it will be outlined how the present inventors acquired the basic idea of the present invention.

As a method for electrically connecting conductor wiring provided for a base member to a solder electrode provided for a semiconductor chip when the gap between the base member and the semiconductor chip is filled with an encapsulation material containing a resin composition, a method in which ultrasonic vibrations are applied to the solder electrode while heating the solder electrode has been known. In that case, the conductor wiring and the solder electrode may be electrically connected together at a relatively low temperature and in a relatively short time compared to a situation where the conductor wiring and the solder electrode are electrically connected together just by heating. In that case, an encapsulant to fill the gap between the base member and the semiconductor chip may be formed by allowing the encapsulation material to cure after the semiconductor chip has been bonded onto the base member.

However, such a process to be performed at a relatively low temperature and for a relatively short time often makes it difficult to remove, during the molding process, the air bubbles created in the encapsulation material, which is a problem with the known process. As a result, if voids remain in the encapsulation material, a semiconductor device fabricated to include an encapsulant made from such an encapsulation material would often cause conduction failures in itself, which is another problem with the known process.

In addition, according to the method disclosed in JP 2011-140617 A, the encapsulation material and the bump electrode are heated to a relatively high temperature of about 180 to 280° C. to melt solder in the bump electrode. Thus, when the encapsulant is formed by heating, molding, and then curing the encapsulation material, voids often remain in the encapsulant due to the components volatilized from the encapsulation material.

Thus, the present inventors carried out extensive research and development to provide an encapsulation material that reduces the chances of creating voids therein or allowing voids to remain in the encapsulant even when molded by conducting a heating treatment at a low temperature of about 130° C. to about 150° C., for example, and for a short time of about 0.5 s to about 2.0 s, thus perfecting our invention. Note that the temperature and duration of the heating treatment described above are only an example and should not be construed as limiting.

Next, the encapsulation material 4 according to an exemplary embodiment will be described. The encapsulation material 4 is used to fill a gap between a base member 2 and a semiconductor chip 3 to be bonded onto the base member 2. The encapsulation material 4 has a reaction start temperature of 160° C. or less. If the encapsulation material 4 is heated to at least one temperature falling within the range from 100° C. to 170° C., the total content of the components volatilized from the encapsulation material 4 is 0.5% by mass or less of the entire encapsulation material 4. According to this embodiment, the reaction start temperature of the encapsulation material 4 is equal to or lower than 160° C. This allows the encapsulant to be molded easily from the encapsulation material 4 even at a relatively low temperature. In addition, when heated to at least one temperature falling within the range from 100° C. to 170° C., the total content of the components volatilized from the encapsulation material 4 is 0.5% by mass or less of the entire encapsulation material 4. This reduces the chances of creating air bubbles when the encapsulation material 4 is molded by heating. Consequently, even if the encapsulant is formed after the encapsulation material 4 according to this embodiment has been molded at a relatively low temperature and in a relatively short time, voids will hardly remain in the encapsulant. The reaction start temperature will be described in detail later in the “2. Details” section.

Using the encapsulation material according to this embodiment reduces the chances of creating voids even if the encapsulant 41 is formed after the encapsulation material 4, arranged in the gap between the base member 2 and the semiconductor chip 3, has been heated and molded at a relatively low temperature and in a relatively short time.

In addition, according to this embodiment, a laminated sheet made of the encapsulation material, a cured product of the encapsulation material, and a semiconductor device including an encapsulant made of the cured product are also provided.

Note that the components volatilized and the voids created by heating the encapsulation material 4 are controllable by adjusting the composition of the respective constituent components of the encapsulation material 4 as will be described in detail later.

### 2. Details

Next, an encapsulation material 4 according to this embodiment will be described. As used herein, “(meth)acrylic-” is a generic term for “acrylic-” and “methacrylic-.” For example, a (meth)acryloyl group is a generic term for an acryloyl group and a methacryloyl group.

As described above, the encapsulation material 4 has a reaction start temperature of 160° C. or less. If the reaction start temperature is equal to or lower than 160° C., the encapsulation material 4 may be easily molded even at a relatively low temperature. This allows the encapsulation material 4 to be molded even without being heated to a high temperature of 180° C. or more when the encapsulant 41 for filling the gap between the base member 2 and the semiconductor chip 3 is formed out of the encapsulation material 4.

In this embodiment, the reaction start temperature is obtained from a melt viscosity curve showing the relationship between the temperature and the melt viscosity in a situation where the melt viscosity is measured with the temperature of the encapsulation material 4 raised. Specifically, the reaction start temperature refers herein to a temperature at which the melt viscosity starts rising in the melt viscosity curve. The encapsulation material 4, for example, melts and comes to have a decreased viscosity within a certain temperature range as the temperature is raised. Allowing a component in the encapsulation material 4 to start reaction at the temperature at which the melt viscosity starts to rise causes the melt viscosity to start rising as well. The reaction start temperature varies according to the chemical makeup in the encapsulation material 4 and is controllable by appropriately adjusting the components in the encapsulation material 4. In this embodiment, the reaction start temperature herein refers to, for example, a temperature higher than a temperature corresponding to the lowest melt viscosity in the melt viscosity curve of the encapsulation material 4 and is a temperature at a viscosity higher by 50 Pa·s than the lowest melt viscosity. As used herein, the “lowest melt viscosity” refers to a viscosity having the smallest value in the melt viscosity curve. Specifically, the melt viscosity, the lowest melt viscosity, and the reaction start temperature may be obtained by the following method.

First, the temperature dependence of the melt viscosity of the encapsulation material 4 is measured using a rheometer under the condition including a temperature range from 100° C. to 300° C., a temperature increase rate of 60° C./min, and an angular velocity of 0.209 rad/s. In this manner, a melt viscosity curve of the encapsulation material 4 is obtained. As the rheometer for use in this measurement, a rheometer with the model number AR2000ex manufactured by TA Instruments, Inc. may be used, for example. Detecting, from the melt viscosity curve thus obtained, the lowest melt viscosity and a temperature corresponding to a melt viscosity that has increased by 50 Pa·s from the lowest melt viscosity allows the reaction start temperature of the encapsulation material 4 to be obtained.

The reaction start temperature of the encapsulation material 4 more preferably falls within the range from 130° C. to 160° C. and even more preferably falls within the range from 140° C. to 150° C.

Furthermore, as described above, if the encapsulation material 4 is heated to at least one temperature falling within the range from 100° C. to 170° C., the total content of components volatilized from the encapsulation material 4 is 0.5 mass % or less of the entire encapsulation material 4. Thus, this reduces the chances of producing air bubbles, caused by volatile components, in the encapsulation material 4 while the encapsulation material 4 is heated and molded.

In this case, it can be said that the “total content of components volatilized from the encapsulation material 4 to the overall encapsulation material 4” is equivalent to the “weight reduction ratio of the encapsulation material 4” caused by heating. Thus, the “total content of components volatilized from the encapsulation material 4 to the overall encapsulation material 4” will be hereinafter sometimes referred to as “weight reduction ratio of the encapsulation material 4.”

The weight reduction ratio of the encapsulation material 4 may be calculated by, for example, the method described in “(1) Evaluation of weight reduction ratio (ratio of volatile components) of encapsulation material 4” in “2. Evaluation tests” of the Examples section.

To measure the weight reduction ratio, for example, first, the weight of the encapsulation material 4 is measured at an ordinary temperature. Subsequently, the encapsulation material 4 is heated for 15 minutes within the air atmosphere at an ordinary pressure. Next, the encapsulation material 4 is left in a dry atmosphere for 30 minutes to be cooled, and then the weight of the encapsulation material 4 is measured. Based on the weight of the encapsulation material 4 yet to be heated and the weight thus obtained of the encapsulation material heated, the weight reduction ratio is calculated as follows:

Weight reduction rate (%)=[(weight before heating)−(weight after heating)]/(weight before heating)×100.

The weight reduction ratio of the encapsulation material 4 is more preferably equal to or less than 0.5% by mass, and even more preferably equal to or less than 0.3% by mass. Particularly, at least if the heating temperature of the encapsulation material 4 is 170° C., the weight reduction ratio of the encapsulation material 4 is preferably equal to or less than 0.5% by mass, more preferably equal to or less than 0.4% by mass, and even more preferably equal to or less than 0.3% by mass.

The melt viscosity of the encapsulation material 4 at the reaction start temperature is preferably equal to or less than 350 Pa·s. If the melt viscosity at the reaction start temperature is equal to or less than 350 Pa·s, then the flowability of the encapsulation material 4 may be increased easily during molding, even when the heating temperature of the encapsulation material 4 is relatively low (e.g., falls within the range from 130° C. to 160° C.) while the encapsulant 41 is formed. Therefore, even if voids such as air bubbles are contained in the encapsulation material 4, the voids may be easily removed out of the encapsulation material 4. Note that the reaction start temperature of the encapsulation material 4 is a measured value obtained by the melt viscosity measurement under a certain condition as described above and is different from the temperature at which the reaction of the encapsulation material 4 actually starts. The curing reaction of the encapsulation material 4 may proceed even at a temperature lower than the reaction start temperature. Therefore, setting the heating temperature in the vicinity of the reaction start temperature when the encapsulant 41 is formed may allow the curing reaction of the encapsulation material 4 to proceed, even if the heating temperature is lower than the reaction start temperature.

The lowest melt viscosity of the encapsulation material 4 is preferably equal to or less than 300 Pa·s. In that case, when the encapsulant 41 is formed out of the encapsulation material 4, the flowability of the encapsulation material 4 may be further increased while the encapsulation material is being heated and molded. Therefore, even if air bubbles, for example, are produced in the encapsulation material 4, the air bubbles may be more easily removable. This further reduces the chances of creating voids in the encapsulant 41.

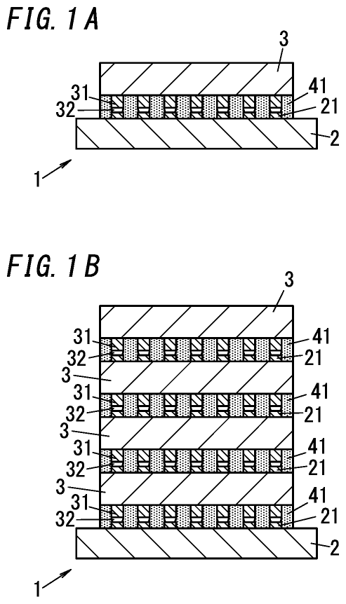

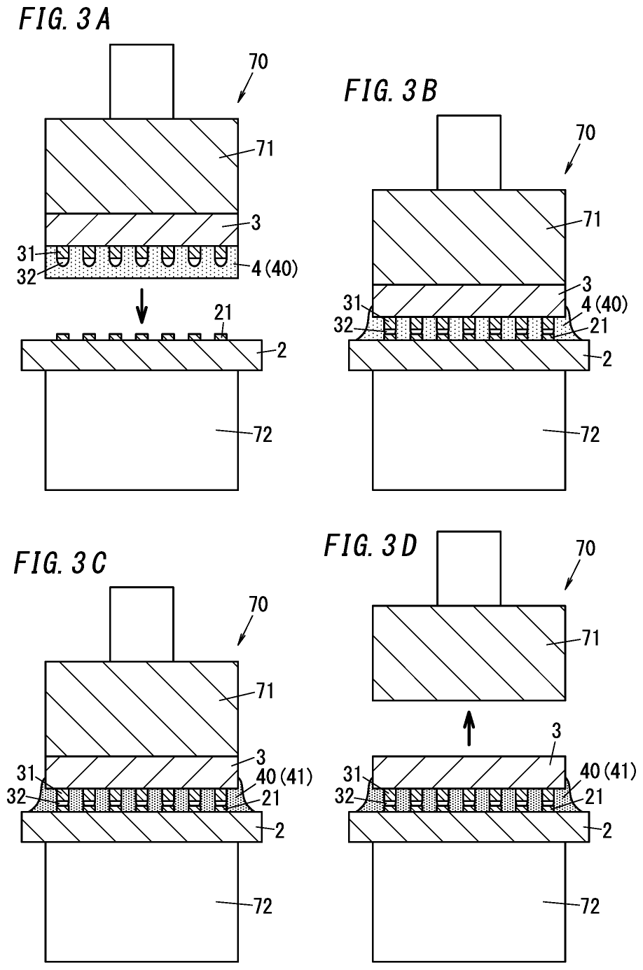

To form the encapsulant 41 out of the encapsulation material 4, the encapsulation material 4 is heated and subjected to ultrasonic vibrations in, for example, a state where the encapsulation material 4 is interposed in the gap between the base member 2 and the semiconductor chip 3 (see FIGS. 3A and 3B). The encapsulation material is melted and caused to flow by heating, and the conductor wiring 21 of the base member 2 and the bump electrodes 31 of the semiconductor chip 3 are joined by ultrasonic vibrations (see FIGS. 3C and 3D). Then, the encapsulation material 4 is further heated and thereby cured to form the encapsulant 41 (see FIG. 1). In this case, heating and curing the encapsulation material 4 in this manner may reduce the chances of creating voids in the encapsulant 41 as described above. Therefore, this reduces, in flip-chip bonding the semiconductor chip 3 bonded onto the base member 2, the chances of creating voids in the encapsulant 41, even when the encapsulation material 4 is heated and the bump electrodes 31 of the semiconductor chip 3 and the conductor wirings 21 of the base member 2 are joined by ultrasonic vibrations.

As can be seen, the encapsulation material 4 may be used suitably as a material for forming the encapsulant 41 to fill the gap between the base member 2 including the conductor wiring 21 and the semiconductor chip 3 including the bump electrodes 31, particularly when the encapsulation material 4 is melted, and the conductor wiring 21 and the bump electrodes 31 are electrically connected together, by applying ultrasonic vibrations to the encapsulation material 4 while heating the encapsulation material 4.

The above-described behavior of the melt viscosity and weight reduction ratio of the encapsulation material 4 may be achieved by appropriately selecting components to be included in the encapsulation material 4 and appropriately adjusting the contents of the components to be included in the encapsulation material 4. A preferred composition of the encapsulation material 4 for achieving such behavior of the melt viscosity and such a weight reduction ratio will be described.

The encapsulation material 4 preferably contains an acrylic compound (A), a polyphenylene ether resin (B) having a substituent (b1) with radical polymerization properties, a thermal radical polymerization initiator (C), and a inorganic filler (D). The encapsulation material 4 containing these components further reduces the number of residual voids in the cured product of the encapsulation material 4. In addition, this also reduces the chances of the encapsulant 41 formed out of the cured product of the encapsulation material 4 peeling off the base member 2. Thus, filling the gap between the base member 2 and the semiconductor chip 3 with the cured product of this encapsulation material 4 would increase the degree of reliability of the semiconductor device 1. Moreover, the encapsulation material 4 containing the polyphenylene ether resin (B), among other things, facilitates adjustment of the melt viscosity of the encapsulation material 4 such that the encapsulation material 4 may have a low melt viscosity. Furthermore, the polyphenylene ether resin (B) includes a substituent (b1) with radical polymerization properties. Thus, when the encapsulation material 4 is thermally cured, polymerization of the polyphenylene ether resin (B) and the acrylic compound (A) forms a macromolecule. That is to say, the polyphenylene ether resin (B) is incorporated into the skeleton of the macromolecule. This allows the cured product of the encapsulation material 4 to have excellent heat resistance and moisture resistance.

In this embodiment, the acrylic compound (A) herein refers to a compound having a (meth)acryloyl group. That is to say, the acrylic compound (A) is a compound having at least one of an acryloyl group or a methacryloyl group. The acrylic compound (A) may contain at least one of a monomer or an oligomer.

The weight reduction ratio of the acrylic compound (A) at a temperature falling within the range from 130° C. to 170° C. is preferably 0.5% or less. If the weight reduction ratio of the acrylic compound (A) is 0.5% or less, the encapsulation material 4 may be easily prepared so that the weight reduction ratio of the encapsulation material 4 will be 0.5% or less. The weight reduction ratio of the acrylic compound (A) may be calculated, for example, by the following method. A thermogravimetric analyzer, such as the model TG/DTA7300 manufactured by Seiko Instruments Inc., is used to heat the encapsulation material 4 from 25° C. to 300° C. at a temperature increase rate of 5° C./min within the air atmosphere and measure a variation in weight with the temperature. From the graph thus obtained, showing the relationship between the temperature and the variation in weight, the weight at the temperature (25° C.) before heating and the weight at 170° C. are read. The weight reduction ratio may be calculated based on the difference in weight before and after the variation in weight.

The viscosity of the acrylic compound (A) at 25° C. preferably falls within the range from 200 mPa·s to 2000 mPa·s. If the viscosity of the acrylic compound (A) falls within this range, a dried product of the encapsulation material 4 may be formed easily, and therefore, may be suitably used as a material for forming the encapsulant 41 out of the encapsulation material 4. The viscosity of the acrylic compound (A) may be obtained based on the result of measurement using a suitable viscometer such as a B-type viscometer manufactured by Toki Sangyo Co., Ltd. (Model number TVB-10) under the condition including a temperature of 25 degrees.

Preferable components that the acrylic compound (A) may contain will be described in more detail.

The acrylic compound (A) includes, for example, a compound having two or more (meth)acryloyl groups per molecule. In this case, the acrylic compound (A) may impart heat resistance to the encapsulant 41. The acrylic compound (A) more preferably contains a compound having two to six (meth)acryloyl groups per molecule, and even more preferably contains a compound having two (meth)acryloyl groups per molecule.

The acrylic compound (A) preferably contains di(meth)acrylate having a structure in which alkylene oxide is added to the bisphenol skeleton. That is to say, the acrylic compound (A) preferably contains a compound having a structure expressed by the following Formula (I). Such a compound will be hereinafter also referred to as an “acrylic compound (A1).”

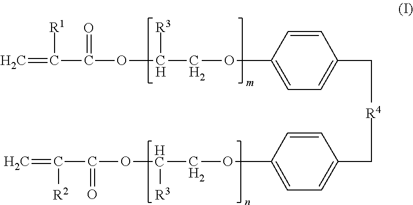

In Formula (I), R¹ and R² are each independently hydrogen or a methyl group, R³ is hydrogen, a methyl group, or an ethyl group, R⁴ is a divalent organic group that connects two aryl groups, and each of m and n is preferably a value falling within the range from 0 to 20, and the average value of m+n is preferably a value falling within the range from 2 to and 30. Examples of R⁴ include a dialkylmethylene group such as dimethylmethylene. The upper and lower limits of m+n are not limited to any particular values, but the lower limit of m+n may be 2, for example, and the upper limit of m+n may be 30, for example.

If the acrylic compound (A) contains the acrylic compound (A1), the weight reduction ratio of the encapsulation material 4 may be further reduced. In addition, since the acrylic compound (A1) has two benzene rings as indicated by Formula (I), high heat resistance may be imparted to the encapsulation material 4.

The acrylic compound (A1) includes, for example, at least one of a compound expressed by the following Formula (II) (hereinafter also referred to as an “acrylic compound (A11)”) or a compound expressed by the following Formula (III) (hereinafter also referred to as an “acrylic compound (A12)”):

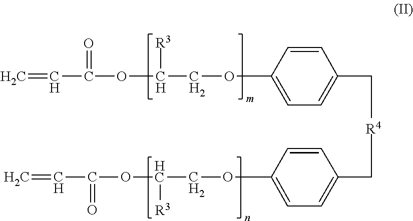

In Formula (II), R³ is hydrogen, a methyl group, or an ethyl group and R⁴ is a divalent organic group that connects two aryl groups. In this case, it is preferred that each of m and n be a value falling within the range from 0 to 20 and the average value of m+n be a value falling within the range from 2 to 30. Examples of R⁴ include a dialkylmethylene group such as dimethylmethylene. The upper and lower limits of m+n are not limited to any particular values, but the lower limit of m+n may be 2, for example, and the upper limit of m+n may be 30, for example. The acrylic compound (A11) is a compound obtained when R¹ and R² are both hydrogen atoms in Formula (I).

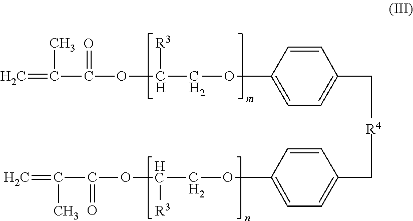

In Formula (III), R³ is hydrogen, a methyl group, or an ethyl group and R⁴ is a divalent organic group that connects two aryl groups. In this case, it is preferred that each of m and n be a value falling within the range from 0 to 20, and the average value of m+n be a value falling within the range from 2 to 30. Examples of R⁴ include a dialkylmethylene group such as dimethylmethylene. The upper and lower limits of m+n are not limited to any particular values, but the lower limit of m+n may be 2, for example, and the upper limit of m+n may be 30, for example. The acrylic compound (A12) is a compound obtained when both R¹ and R² are methyl groups in Formula (I).

The acrylic compound (A) more preferably contains the acrylic compound (A12). In that case, the weight reduction ratio of the encapsulation material 4 may be reduced particularly significantly. This further reduces the chances of creating voids in the encapsulant 41 formed out of the encapsulation material 4.

More specific examples of the acrylic compound (A1) include EO-modified bisphenol A-type di(meth)acrylate (where m+n=2.3 to 30) such as Aronix M-210 and M-211B (manufactured by Toagosei Co., Ltd.), and ABE-300, A-BPE-4, A-BPE-6, A-BPE-10, A-BPE-20, A-BPE-30, BPE-100, BPE-200, BPE-500, BPE-900, and BPE-1300N (manufactured by Shin Nakamura Chemical Co., Ltd.); and EO-modified bisphenol F-type di(meth)acrylate such as Aronix M-208 (manufactured by Toagosei Co., Ltd.).

If the acrylic compound (A) contains the acrylic compound (A1), the content of the acrylic compound (A1) with respect to the total mass of the acrylic compound (A) preferably falls within the range from 60% by mass to 100% by mass. This facilitates further lowering the reaction start temperature of the encapsulation material 4. In addition, in this case, the weight reduction ratio of the encapsulation material 4 may be easily 0.5% or less at any temperature falling within the range from 100° C. to 170° C. In particular, if the acrylic compound (A) contains the acrylic compound (A12), the content of the acrylic compound (A12) with respect to the total mass of the acrylic compound (A) preferably falls within the range from 60% by mass to 100% by mass. This particularly significantly reduces the chances of creating voids in the encapsulant 41 formed out of the encapsulation material 4. As used herein, the “entire acrylic compound (A)” means the total content of components contained as the acrylic compound (A) in the encapsulation material 4.

The acrylic compound (A) may contain a compound having two (meth)acryloyl groups per molecule (which will be hereinafter also referred to as an “acrylic compound (A2)”) and different from the above-mentioned acrylic compound (A1).

The acrylic compound (A2) may include (meth)acrylate having a crosslinked polycyclic structure (hereinafter also referred to as an “acrylic compound (A21)”). Specifically, examples of the acrylic compound (A21) include a compound expressed by the following Formula (IV) (hereinafter also referred to as an “acrylic compound (A211)”) and a compound expressed by the following Formula (V) (hereinafter also referred to as an “acrylic compound (A212)”). If the encapsulation material 4 contains at least one of the acrylic compound (A211) or the acrylic compound (A212), that contributes to further lowering the viscosity of the encapsulation material 4. In addition, in that case, the heat resistance of the encapsulant 41 may be further improved.

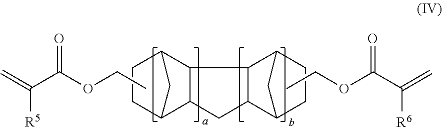

In Formula (IV), R⁵ and R⁶ are each independently a hydrogen atom or a methyl group, a is 1 or 2, and b is 0 or 1.

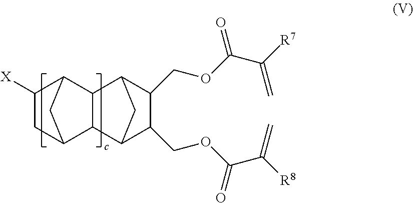

In Formula (V), R⁷ and R⁸ are each independently a hydrogen atom or a methyl group, X is a hydrogen atom, a methyl group, a methylol group, an amino group, or a (meth)acryloyloxymethyl group, and c is 0 or 1.

Specific examples of the acrylic compound (A21) include: a (meth)acrylate having a dicyclopentadiene skeleton and expressed by Formula (IV) in which a is 1 and b is 0; a (meth)acrylate having perhydro-1,4:5,8-dimethanonaphthalene skeleton and expressed by Formula (V) in which c is 1; a (meth)acrylate having a norbornane skeleton and expressed by Formula (V) in which c is 0; dicyclopentadienyl diacrylate (tricyclodecane dimethanol diacrylate) expressed by Formula (IV) in which R⁵ and R⁶ are hydrogen atoms, a=1 and b=0; perhydro-1,4:5,8-dimethanonaphthalene-2,3,7-trimethylol triacrylate expressed by Formula (V) in which X is an acryloyloxymethyl group, R⁷ and R⁸ are hydrogen atoms, and c is 1; norbornane dimethylol diacrylate expressed by Formula (V) in which X, R⁷, and R⁸ are hydrogen atoms and c is 0; and perhydro-1,4:5,8-dimethanonaphthalene-2,3-dimethylol diacrylate expressed by Formula (V) in which X, R⁷, and R⁸ are hydrogen atoms and c is 1. Among other things, the acrylic compound (A21) preferably contains at least one of dicyclopentadienyl diacrylate or norbornane dimethylol diacrylate.

More specific examples of the acrylic compound (A2) include ethylene glycol di(meth)acrylate, 1,4-butanediol di(meth)acrylate, 1,6-hexanediol di(meth)acrylate, 1,9-nonanediol di(meth)acrylate, 1,3-butanediol di(meth)acrylate, neopentyl glycol di(meth)acrylate, dimer diol di(meth)acrylate, dimethylol tricyclodecane di(meth)acrylate, diethylene glycol di(meth)acrylate, triethylene glycol di(meth)acrylate, tetraethylene glycol di(meth)acrylate, polyethylene glycol di(meth)acrylate, tripropylene glycol di(meth)acrylate, polypropylene glycol di(meth)acrylate, glycerin di(meth)acrylate, trimethylol propane di(meth)acrylate, pentaerythritol di(meth)acrylate, zinc di(meth)acrylate, cyclohexanediol di(meth)acrylate, cyclohexane-dimethanol di(meth)acrylate, cyclohexanediethanol di(meth)acrylate, cyclohexanedialkyl alcohol di(meth)acrylate, and dimethanol tricyclodecane di(meth)acrylate.

The content of the acrylic compound (A2) with respect to the total mass of the acrylic compound (A) preferably falls within the range from 0% by mass to 40% by mass. This allows the weight reduction ratio and the melt viscosity of the encapsulation material 4 to be easily adjusted, and further reduces the chances of creating voids in the encapsulant 41 when the encapsulant 41 is formed out of the encapsulation material 4. The content of the acrylic compound (A2) with respect to the total mass of the acrylic compound (A) more preferably falls within the range from 10% by mass to 30% by mass, and even more preferably falls within the range from 15% by mass to 25% by mass.

The acrylic compound (A) may contain, for example, a reaction product of 1 mol of bisphenol A, bisphenol F, or bisphenol AD and 2 mol of glycidyl acrylate, and a reaction product of 1 mol of bisphenol A, bisphenol F, or bisphenol AD and 2 mol of glycidyl methacrylate. Specifically, the acrylic compound (A) may include, for example, PO-modified bisphenol A-type di(meth)acrylate (where n=2 to 20) such as Denacol acrylate DA-250 (manufactured by Nagase ChemteX Corporation) and Viscoat 540 (manufactured by Osaka Organic Chemical Industry Ltd.) and PO-modified phthalic acid diacrylate such as Denacol Acrylate DA-721 (manufactured by Nagase ChemteX Corporation).

It is also preferred that the acrylic compound (A) further contain an epoxy (meth)acrylate. That is to say, the acrylic compound (A) preferably contains an epoxy (meth)acrylate. In this case, particularly when the acrylic compound (A) contains an epoxy group, the reactivity of the encapsulation material 4 may be improved and the heat resistance and adhesion of the encapsulant 41 may be improved. As used herein, an “epoxy (meth)acrylate” refers to a compound having at least one epoxy group and at least two (meth)acryloyl groups in one molecule. Also, epoxy (meth)acrylate is a compound that is included in neither the acrylic compound (A1) nor the acrylic compound (A2) described above.

Epoxy (meth)acrylate is an oligomer that is an addition reaction product of, for example, an epoxy resin and an unsaturated monobasic acid such as acrylic acid or methacrylic acid.

The epoxy resin, which is a raw material of epoxy (meth)acrylate, includes a diglycidyl compound (bisphenol type epoxy resin) obtained by condensation of bisphenols, which are typically bisphenols such as bisphenol A and bisphenol F, with epihalohydrin. The epoxy resin may include an epoxy resin having a phenol skeleton. The epoxy resin having a phenol skeleton may be, for example, a polyvalent glycidyl ether (phenol-novolac type epoxy resin or a cresol-novolac type epoxy resin) obtained by condensation of a phenol-novolac, which is a condensation product of phenol or cresol and aldehyde such as formalin, with epihalohydrin. The epoxy resin may include an epoxy resin having a cyclohexyl ring.

The epoxy (meth)acrylate preferably contains, for example, a bisphenol A type epoxy acrylate which is either a solid or a liquid having a viscosity of 10 Pa·s or more at 25° C. The bisphenol A type epoxy acrylate is expressed by, for example, the following Formula (VI):

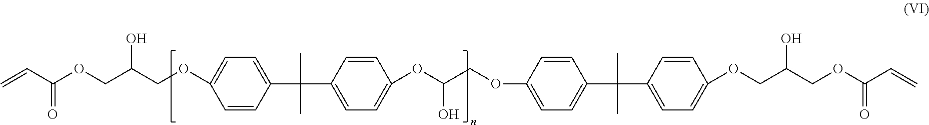

In Formula (VI), n represents a positive integer.

Examples of commercially available bisphenol A-type epoxy acrylates are Denacol Acrylate DA-250 (manufactured by Nagase ChemteX Corporation; 60 Pa·s at 25° C.), Denacol Acrylate DA-721 (manufactured by Nagase ChemteX Corporation; 100 Pa·s at 25° C.), Ripoxy VR-60 (manufactured by Showa High Polymer Co., Ltd.; solid at an ordinary temperature), and Ripoxy VR-77 (manufactured by Showa High Polymer Co., Ltd.; 100 Pa·s at 25° C.).

The content of the epoxy (meth)acrylate with respect to the total mass of the acrylic compound (A) preferably falls within the range from, for example, 5% by mass to 15% by mass. In that case, the adhesion between the base member 2 and the encapsulant 41 may be further improved. The content of the epoxy (meth)acrylate with respect to the total mass of the acrylic compound (A) more preferably falls within the range from 7% by mass to 10% by mass.

If the acrylic compound (A) includes a compound having three or more (meth)acryloyl groups, examples of the compound having three or more (meth)acryloyl groups include pentaerythritol triacrylate, pentaerythritol tetraacrylate, pentaerythritol pentaacrylate, ethoxylated (3) trimethylolpropane triacrylate, ethoxylated (6) trimethylolpropane triacrylate, ethoxylated (9) trimethylolpropane triacrylate, propoxylated (6) trimethylolpropane triacrylate, propoxylated (3) glyceryl triacrylate, highly propoxylated (55) glyceryl triacrylate, ethoxylated (15) trimethylolpropane triacrylate, trimethylolpropane trimethacrylate, tetraethylene glycol diacrylate, dimethylolpropane tetraacrylate, tripropylene glycol diacrylate, pentaacrylate ester, 1,3-adamantane diol dimethacrylate, 1,3-adamantane diol diacrylate, 1,3-adamantane dimethanol dimethacrylate, and 1,3-adamantane dimethanol diacrylate.

It is also preferred that the acrylic compound (A) further contain (meth)acrylate having a fluorene skeleton. This would contribute to further improving the heat resistance of the encapsulation material 4. Examples of the (meth)acrylate having the fluorene skeleton include at least one compound selected from the group consisting of bisphenoxyethanolfluorene, 4,4′-(9-fluorenylidene) diphenol, biscresolfluorene, and bisanilinefluorene.

The acrylic compound (A) may contain any of various vinyl monomers other than the components described above. For example, the acrylic compound (A) may contain a monofunctional vinyl monomer.

The content of the acrylic compound (A) with respect to the total solid content of the encapsulation material 4 falls, for example, within the range from 10% by mass to 30% by mass. Note that the content of the acrylic compound (A) with respect to the total solid content of the encapsulation material 4 does not have to fall within this range.

The polyphenylene ether resin (B) will be described. As described above, the polyphenylene ether resin (B) has a radically polymerizable substituent (b1) at a terminal thereof. The polyphenylene ether resin (B) has, for example, a polyphenylene ether chain (b2) and a substituent (b1) bonded to the end of the polyphenylene ether chain (b2).

The substituent (b1) may have any structure without limitation as long as the substituent (b1) is radically polymerizable. Examples of the substituent (b1) include a group with a carbon-carbon double bond.

The substituent (b1) is preferably a group having a carbon-carbon double bond. In this case, allowing the substituent (b1) to react with the acrylic compound (A) causes the polyphenylene ether resin (B) to be incorporated into the skeleton of the macromolecule. As a result, the cured product of the encapsulation material 4 comes to have excellent heat resistance and moisture resistance.

The weight reduction ratio of the polyphenylene ether resin (B) is, for example, 0.5% or less. Therefore, the polyphenylene ether resin (B) has excellent heat resistance. Consequently, the polyphenylene ether resin (B) may reduce the chances of creating voids in the encapsulant 41 when the encapsulation material 4 is heated. The weight reduction ratio of the polyphenylene ether resin (B) may be measured by the same method as the one applied to the acrylic compound (A).

The substituent (b1) may have, for example, the structure expressed by the following Formula (1) or the structure expressed by the following Formula (2):

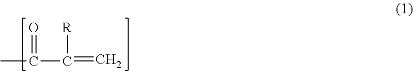

In Formula (1), R is hydrogen or an alkyl group. If R is an alkyl group, the alkyl group is preferably a methyl group.

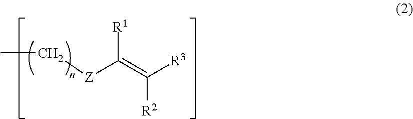

In Formula (2), n is an integer falling within the range from 0 to 10 and n=1, for example. In Formula (2), Z is an arylene group and R¹ to R³ are each independently hydrogen or an alkyl group. If n is 0 in Formula (2), then Z is directly bonded to the end of the polyphenylene ether chain (c1) in the polyphenylene ether resin (C).

The substituent (b1) preferably has the structure expressed by Formula (1), in particular.

The polyphenylene ether resin (B) may contain, for example, a compound having the structure expressed by the following Formula (3):

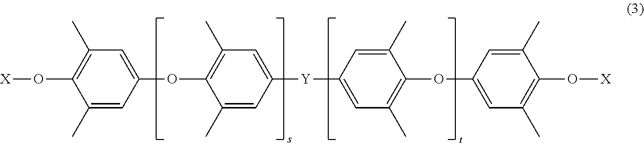

In Formula (3), Y is an alkylene group having 1 to 3 carbon atoms or a direct bond. Y may be a dimethylmethylene group, for example. In Formula (3), X is a substituent (b1) and may be, for example, a group having the structure expressed by Formula (1) or a group having the structure expressed by Formula (2). It is particularly recommended that X be a group having the structure expressed by Formula (1). In Formula (3), s is a number equal to or greater than zero, t is a number equal to or greater than zero, and the sum of s and t is a number equal to or greater than one. In Formula (3), s is preferably a number falling within the range from 0 to 20, t is preferably a number falling within the range from 0 to 20, and the sum of s and t is preferably a number falling within the range from 1 to 30.

The content of the polyphenylene ether resin (B) preferably falls within the range from 20% by mass to 80% by mass with respect to 100 parts by mass in total of the acrylic compound (A), the polyphenylene ether resin (B), and the thermoplastic resin to be described later. If this content is 20% by mass or more, the cured product of the encapsulation material 4 may have higher heat resistance. If this content is 80% by mass or less, the cured product may have higher flexibility. This content more preferably falls within the range from 25% by mass to 50% by mass.

The encapsulation material 4 may further contain a thermosetting compound other than the acrylic compound (A) and the polyphenylene ether resin (B). Examples of such thermosetting compounds include compounds that cause a thermosetting reaction with the acrylic compound (A). Specific examples of such thermosetting compounds include a bismaleimide resin.

The encapsulation material 4 may contain an elastomer. Examples of the elastomers include maleic anhydride adducts of isoprene polymers.

The encapsulation material 4 may contain a thermoplastic resin. It is preferred that the thermoplastic resin be a component that hardly volatilizes at a temperature falling within the range from 100° C. to 170° C. Examples of the thermoplastic resin include a copolymer of methyl methacrylate and n-butyl methacrylate. If the encapsulation material 4 contains a thermoplastic resin, the encapsulation material 4 may be molded into a sheet shape with improved moldability. The content of the thermoplastic resin preferably falls within the range from 20% by mass to 80% by mass with respect to 100 parts by mass in total of the acrylic compound (A), the polyphenylene ether resin (B), and the thermoplastic resin.

The thermal radical polymerization initiator (C) contains, for example, an organic peroxide. The one-minute half-life temperature of the organic peroxide preferably falls within the range from 100° C. to 195° C., and more preferably falls within the range from 120° C. to 180° C. In that case, increasing the viscosity of the encapsulation material 4 quickly enough not to impair the wettability between the bump electrodes 31 and the conductor wiring 21 in the initial stage of the step of heating and curing the encapsulation material 4 reduces the number of voids created. Further, advancing the curing reaction of the encapsulation material 4 sufficiently rapidly allows peeling between the semiconductor chip 3 and the encapsulant 41 to be reduced.

Specific examples of the organic peroxide include t-butyl peroxy-2-ethylhexyl monocarbonate (with a one minute half-life temperature of 161.4° C.), t-butyl peroxy benzoate (with a one-minute half-life temperature of 166.8° C.), t-butyl cumyl peroxide (with a one minute half-life temperature of 173.3° C.), dicumyl peroxide (with a one minute half-life temperature of 175.2° C.), α, α′-di (t-butylperoxy) diisopropylbenzene (with a one minute half-life temperature of 175.4° C.), 2,5-dimethyl-2,5-di(t-butylperoxy) hexane (with a one minute half-life temperature of 179.8° C.), di-t-butylperoxide (with a one minute half-life temperature of 185.9° C.), and 2,5-dimethyl-2,5-bis(t-butylperoxy) hexine (with a one minute half-life temperature of 194.3° C.).

The content of the thermal radical polymerization initiator (C) preferably falls within the range from 0.25 parts by mass to 2.0 parts by mass with respect to 100 parts by mass in total of the acrylic compound (A) and the polyphenylene ether resin (B). This allows the cured product to have good physical properties. The content of the thermal radical polymerization initiator (C) more preferably falls within the range from 0.5 parts by mass to 1.5 parts by mass.

In this embodiment, it is also recommended that the encapsulation material 4 further contain an inorganic filler (D). The encapsulation material 4 containing the inorganic filler (D) further reduces the number of voids created in the encapsulant 41 when the gap between the base member 2 and the semiconductor chip 3 is filled by applying ultrasonic vibrations to the encapsulation material 4 while heating the encapsulation material 4. In addition, this further reduces the chances of the encapsulant 41 peeling off either the base member 2 or the semiconductor chip 3. On top of that, the inorganic filler (D) allows the coefficient of thermal expansion of the encapsulant 41 made of the cured product of the encapsulation material 4 to be controlled. Furthermore, the inorganic filler (D) increases the thermal conductivity of the encapsulant 41, thus allowing the heat generated from the semiconductor chip 3 to be efficiently dissipated via the encapsulant 41.

Examples of the inorganic filler (D) may contain at least one material selected from the group consisting of: silica powders such as fused silica, synthetic silica, and crystalline silica; oxides such as alumina and titanium oxide; silicates such as talc, calcined clay, uncalcined clay, mica and glass; carbonates such as calcium carbonate, magnesium carbonate, and hydrotalcite; hydroxides such as aluminum hydroxide, magnesium hydroxide, and calcium hydroxide; sulfates or sulfites such as barium sulfate, calcium sulfate, and calcium sulfite; borates such as zinc borate, barium metaborate, aluminum borate, calcium borate and sodium borate; and nitrides such as aluminum nitride, boron nitride and silicon nitride. The fused silica may be either fused spherical silica or fused crushed silica, whichever is appropriate. The inorganic filler (D) particularly preferably contains at least one of silica or alumina.

The inorganic filler (D) may have a crushed, needlelike, scaled, spherical, or any other appropriate shape without limitation. To increase the dispersibility of the inorganic filler (D) in the encapsulation material 4 and to control the viscosity of the encapsulation material 4, the inorganic filler (D) preferably has a spherical shape.

The inorganic filler (D) suitably has a mean particle size smaller than the gap distance between the base member 2 and the semiconductor chip 3 mounted on the base member 2.

To increase the fill density of the inorganic filler (D) in the encapsulation material 4 and the encapsulant 41 and to control the viscosity of the encapsulation material 4, the inorganic filler (D) preferably has a mean particle size falling within the range from 0.2 μm to 0.5 μm and more preferably has a mean particle size falling within the range from 0.2 μm to 0.4 μm. Note that in this embodiment, the mean particle size is a median diameter calculated based on the result of particle size distribution measurement by laser beam diffraction.

To control the viscosity of the encapsulation material 4 and control the physical properties of the encapsulant 41, the inorganic filler (D) may contain two or more types of components with mutually different mean particle sizes.

The content of the inorganic filler (D) may fall, for example, with the range from 10% by mass to 90% by mass with respect to the solid content of the encapsulation material 4.

The encapsulation material 4 may contain a flux. Examples of the fluxes include an organic acid. If the encapsulation material 4 contains an organic acid, the action of the organic acid allows a surface oxide film to be removed from the bump electrodes 31 during the reflow process, thus ensuring good reliability of connection between the semiconductor chip 3 and the base member 2. The organic acid may contain at least one compound selected from the group consisting of sebacic acid, abietic acid, glutaric acid, succinic acid, malonic acid, oxalic acid, adipic acid, pimelic acid, suberic acid, azelaic acid, diglycolic acid, thiodiglycolic acid, phthalic acid, isophthalic acid, terephthalic acid, propanetricarboxylic acid, citric acid, benzoic acid, and tartaric acid. The content of the organic acid preferably falls within the range from 0.1% by mass to 20% by mass, and more preferably falls within the range from 0.1% by mass to 10% by mass, with respect to the solid content of the encapsulation material 4.

The encapsulation material 4 may contain maleic acid-modified polybutadiene. The encapsulation material 4 containing the maleic acid-modified polybutadiene increases the adhesion between the encapsulant 41 and the base member 2 particularly significantly. The content of the maleic acid-modified polybutadiene preferably falls within the range from 10% by mass to 30% by mass with respect to the acrylic compound (A).

The encapsulation material 4 may further contain appropriate constituting components of resin such as epoxy compounds and phenolic compounds. Examples of the epoxy compounds include at least one component selected from the group consisting of: alkyl-phenol-novolac type epoxy resins such as phenol-novolac type epoxy resins and cresol-novolac type epoxy resins; naphthol-novolac type epoxy resins; phenol-aralkyl type epoxy resins having a phenylene skeleton, a biphenylene skeleton, or any other skeleton; biphenyl-aralkyl type epoxy resins; naphthol-aralkyl type epoxy resins having a phenylene skeleton, a biphenylene skeleton, or any other skeleton; polyfunctional epoxy resins such as triphenolmethane type epoxy resin and alkyl modified triphenolmethane type epoxy resin; triphenylmethane type epoxy resins; tetrakisphenolethane type epoxy resins; dicyclopentadiene type epoxy resins; stilbene type epoxy resins; bisphenol-type epoxy resins such as bisphenol A type epoxy resins and bisphenol F type epoxy resins; biphenyl-type epoxy resins; naphthalene-type epoxy resins; alicyclic epoxy resins; brome-containing epoxy resins such as bisphenol A-type brome-containing epoxy resin; glycidyl-amine type epoxy resins obtained by reaction of polyamine such as diaminodiphenylmethane or isocyanuric acid and epichlorohydrin; and glycidyl ester type epoxy resins obtained by reaction of a polybasic acid such as phthalic acid or dimer acid with epichlorohydrin. Examples of the phenolic compounds include at least one component selected from the group consisting of: phenolic resins, more specifically, novolac type resins such as phenol-novolac resins, cresol-novolac resins, and naphthol-novolac resins; dicyclopentadiene type phenol-novolac resins, dicyclopentadiene type naphthol-novolac resins and other dicyclopentadiene type phenolic resins; terpene modified phenolic resins; bisphenol type resins such as bisphenol A and bisphenol F; and triazine modified novolac resins. If the encapsulation material 4 contains an epoxy compound, the encapsulation material 4 may further contain a curing accelerator that accelerates curing of the epoxy compound.

The encapsulation material 4 may contain a radical scavenger as long as the advantages of this embodiment are not marred. That is to say, the encapsulation material 4 may or may not contain a radical scavenger. If the encapsulation material 4 contains a radical scavenger, even radicals generated in the encapsulation material 4 when the encapsulation material 4 is heated may be scavenged by the radical scavenger. This slows down the advancement of the thermal radical reaction in the encapsulation material 4, thus reducing the thermal radical reaction when the encapsulation material 4 is heated and melted. This allows the reactivity of the encapsulation material 4 being heated to be controlled, thus making the viscosity of the encapsulation material 4 controllable.

Examples of radical scavengers include nitroxide compounds and carbonylthio compounds. The encapsulation material 4 containing a nitroxide compound allows, when the encapsulation material 4 is melted by heating, the advancement of the initial thermal radical reaction to be slowed down moderately.

Examples of nitroxide compounds include at least one component selected from the group consisting of: 2,2,6,6-tetramethyl-1-piperidineoxy free radical (TEMPO); 4-acetamido-2,2,6,6-tetraethylpiperidine-1-oxy free radical; 4-amino-2,2,6,6-tetramethylpiperidine-1-oxy free radical; 4-carboxy-2,2,6,6-tetramethylpiperidine-1-oxy free radical; 4-oxo-2,2,6,6-tetramethyl-piperidine-1-oxy free radical; 4-methacryloyloxy-2,2,6,6-tetramethylpiperidine-1-oxy free radical; and [[N,N′-[adamantan-2-ylidenebis(1,4-phenylene)] bis (tert-butylamine)]-N,N′-diylbisoxy] radical. The content of the nitroxide compound preferably falls within the range from 2.5% by mass to 20% by mass with respect to the thermal radical polymerization initiator (C).

The encapsulation material 4 may contain additives other than the components described above as long as the advantages of this embodiment are not marred. Examples of additives include silane coupling agents, defoamers, leveling agents, low stress agents, and pigments.

The encapsulation material 4 is obtained by compounding the respective components described above and molding the resultant mixture as needed. The encapsulation material 4 may be prepared by, for example, the following method.

First, all components, but the inorganic filler (D), of the encapsulation material 4 described above are compounded together either simultaneously or sequentially to obtain a mixture. This mixture is then stirred up and blended while being subjected to heating or cooling treatment as needed. Next, the inorganic filler (D) is added to the mixture depending on the necessity. Subsequently, the mixture is once again stirred up and blended while being subjected to heating or cooling treatment as needed. In this manner, the encapsulation material 4 may be obtained. To stir up the mixture, a disper, a planetary mixer, a ball mill, a three-roll mill, a bead mill, and other mixers may be used in combination as needed, for example.

The encapsulation material 4 may be molded into, for example, a sheet shape or a paste shape. It is recommended that the encapsulation material 4 be molded into a sheet shape. In other words, the encapsulation material 4 preferably has a sheet shape. The encapsulation material 4 is suitable to making the encapsulant 41 of the semiconductor device 1 (see FIG. 1). Note that the encapsulation material 4 does not have to have one of these shapes.

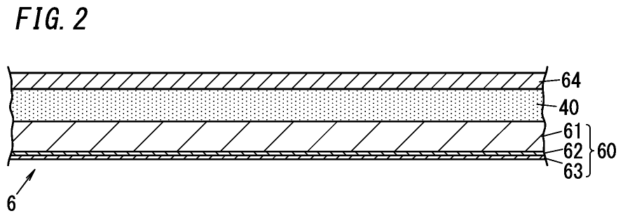

An encapsulation material 4 in a sheet shape (hereinafter referred to as a “sheet member 40”) and a laminated sheet 6 including the sheet member 40 will be described in detail with reference to FIG. 2.

When the sheet member 40 is formed, first, a composition in liquid phase is prepared by adding, as needed, a solvent to the mixture containing the components described above, for example. Examples of the solvent include at least one component selected from the group consisting of methanol, ethanol, ethylene glycol monomethyl ether, ethylene glycol monoethyl ether, ethylene glycol monobutyl ether, methyl ethyl ketone, acetone, isopropylacetone, toluene, and xylene. In this case, the content of the solvent to add may be set appropriately. For example, the content of the solvent may fall within the range from 20% by mass to 80% by mass with respect to the total solid content of the encapsulation material 4. Note that the solvent is vaporizable when the sheet member is obtained by forming the liquid composition into a sheet shape.

In addition, a supporting sheet 60 is provided. The supporting sheet 60 may include an appropriate plastic sheet 61 of polyethylene terephthalate, for example. Optionally, the supporting sheet 60 may include the plastic sheet 61 and a pressure-sensitive adhesive layer 62 stacked on the plastic sheet 61. The pressure-sensitive adhesive layer 62 is a layer with a moderate degree of pressure-sensitive adhesive force and may be used to secure the supporting sheet 60 onto an appropriate base. The pressure-sensitive adhesive layer 62 may have reaction curability. In that case, the supporting sheet 60 may be firmly secured to an appropriate base by allowing the pressure-sensitive adhesive layer 62 to cure after the supporting sheet 60 has been placed on the base. The pressure-sensitive adhesive layer 62 may be made from at least one component selected from the group consisting of, for example, an acrylic resin, synthetic rubber, natural rubber, or a polyimide resin, for example.

The liquid composition is applied onto one surface of the supporting sheet 60. If the supporting sheet 60 includes the plastic sheet 61 and the pressure-sensitive adhesive layer 62, then the liquid composition is applied onto a surface, opposite from the pressure-sensitive adhesive layer 62, of the plastic sheet 61. Subsequently, the liquid composition is dried or semi-cured by heating the liquid composition on the supporting sheet 60. In this case, the liquid composition is preferably heated under the condition including a heating temperature of 60° C. to 120° C. and a heating duration of 5 to 30 minutes, for example. This allows the sheet member 40 to be formed on the supporting sheet 60 and a laminated sheet 6 including the sheet member 40 and the supporting sheet 60 to support the sheet member 40 thereon to be obtained. The encapsulation material 4 containing the polyphenylene ether resin (B) facilitates molding the encapsulation material 4 into a sheet shape, thus making it particularly easy to make the sheet member 40.

The sheet member 40 may have a thickness falling within the range from 10 μm to 50 μm, for example. However, this is only an example and should not be construed as limiting. Alternatively, the sheet member 40 may have any other appropriate thickness to be selected according to the thickness of the encapsulant 41 of the semiconductor device 1.

Optionally, the laminated sheet 6 may further include a protective film 64 that coats the sheet member 40 as shown in FIG. 2. The material for the protective film 64 is not particularly limited. Also, if the supporting sheet 60 includes the pressure-sensitive adhesive layer 62, then laminated sheet 6 may further include a coating sheet 63 that coats the pressure-sensitive adhesive layer 62 as shown in FIG. 2. The material for the coating sheet 63 is not particularly limited, either.

A cured product of the encapsulation material 4 is obtained by thermally curing the encapsulation material 4. The cured product of the encapsulation material 4 is suitably used as an encapsulant 41 that fills the gap between the base member 2 and the semiconductor chip 3 mounted onto the base member 2. The encapsulation material 4 placed in the gap between the base member 2 and the semiconductor chip 3 is heated and subjected to ultrasonic vibrations. This reduces, even when the encapsulant 41 is formed out of the encapsulation material 4 by molding and curing the encapsulation material 4, the chances of creating voids in the encapsulant 41.

The glass transition temperature of the cured product is preferably equal to or higher than 130° C. In that case, the cured product may have high heat resistance, and therefore, the semiconductor device 1 including the encapsulant 41 made of the cured product may have an excellent degree of heat resistance reliability. If the encapsulation material 4 contains the polyphenylene ether resin (B), such a glass transition temperature is easily achievable by appropriately controlling the composition of the encapsulation material 4.

The encapsulation material 4 is effectively usable as an underfill encapsulant. A semiconductor device 1 may be fabricated by filling, with this encapsulation material 4, the gap between the base member 2 and the semiconductor chip 3 by pre-applied underfilling.

FIG. 1A illustrates an example of the semiconductor device 1. This semiconductor device 1 includes a base member 2, a semiconductor chip 3 bonded facedown onto the base member 2, and an (underfill) encapsulant 41 that fills the gap between the base member 2 and the semiconductor chip 3. The encapsulant 41 is a cured product of an encapsulation material 4. The semiconductor chip 3 includes bump electrodes 31 on its surface facing the base member 2. Meanwhile, the base member 2 has conductor wiring 21 on its surface facing the semiconductor chip 3. The bump electrodes 31 and the conductor wiring 21 are aligned with each other and connected together via solder bumps 32. These bump electrodes 31 and the conductor wiring 21 are embedded in the encapsulant 41.

A method for fabricating the semiconductor device 1 according to this embodiment includes providing a base member 2 having conductor wiring 21, an encapsulation material 4, and a semiconductor chip 3 with bump electrodes 31. The method further includes: providing the semiconductor chip 3 having the bump electrodes 31, with the encapsulation material 4 interposed between the bump electrode 31 and a surface, having the conductor wiring 21, of the base member 2, such that the conductor wiring 21 faces the bump electrodes 31. The method further includes applying, in this state, ultrasonic vibrations to the encapsulation material 4 while heating the encapsulation material 4 to fill the gap between the base member 2 and the semiconductor chip 3 and electrically connect the conductor wiring 21 to the bump electrodes 31. Subsequently, an encapsulant 41 is formed out of the cured product of the encapsulation material 4 by further heating and completely curing the encapsulation material 4. In this manner, a semiconductor device 1, in which the gap between the base member 2 and the semiconductor chip 3 is filled with the encapsulant 41 with a reduced number of voids, may be fabricated.

Next, an exemplary method for fabricating the semiconductor device 1 will be described in further detail with reference to FIGS. 3A-3D.

First, a base member 2, a semiconductor chip 3, and a laminated sheet 6 including an encapsulation material 4 (sheet member 40) are provided.

The base member 2 may be a motherboard, a package board, or an interposer board, for example. In this embodiment, the base member 2 includes an insulating substrate made of glass epoxy, polyimide, polyester, a ceramic, or any other suitable material and conductor wiring 21 made of an electrical conductor such as copper and formed on its surface.

The semiconductor chip 3 includes, on one surface of a silicon wafer including a circuit that has been formed by an appropriate method such as a photolithographic process, bump electrodes 31 which are electrically connected to the circuit. In this embodiment, the bump electrodes 31 of the semiconductor chip 3 include solder bumps 32. Alternatively, not the bump electrodes 31 but the conductor wiring 21 on the base member 2 may include the solder bumps 32. Still alternatively, each of the bump electrodes 31 and the conductor wiring 21 may include the solder bumps 32. In other words, at least one of the bump electrodes 31 of the semiconductor wafer or the conductor wiring 21 of the base member 2 may include the solder bumps 32. The solder bumps 32 are suitably made of lead-free solder having a melting point of 210° C. or more such as Sn-3.5Ag (with a melting point of 221° C.), Sn-2.5Ag-0.5Cu-1Bi (with a melting point of 214° C.), Sn-0.7Cu (with a melting point of 227° C.), or Sn-3Ag-0.5Cu (with a melting point of 217° C.).

The semiconductor chip 3 may be formed out of an individual sheet that has been cut to appropriate dimensions out of a stack of the laminated sheet 6 and a semiconductor wafer. Specifically, the individual sheet may be obtained in the following manner. First, the sheet member 40 of the laminated sheet 6 may be laid over the surface, having the bump electrodes 31, of the semiconductor wafer, for example. In this process step, after the protective film 64 has been stripped from the sheet member 40 of the laminated sheet 6, the sheet member 40 laid on top of the supporting sheet 60 is further laid over the surface, having the bump electrodes 31, of the semiconductor wafer. Next, the semiconductor wafer is diced by cutting off the semiconductor wafer with the sheet member 40 still attached thereto. In this case, after the coating sheet 63 has been stripped from the pressure-sensitive adhesive layer 62 of the supporting sheet 60, the pressure-sensitive adhesive layer 62 may be placed on a base and then allowed to cure as needed, for example. In this manner, the supporting sheet 60 is fixed on the base with the sheet member 40 laid on top of the supporting sheet 60. In this state, the semiconductor wafer is cut off with the sheet member 40 still attached thereto. As a result, a plurality of members, each including a semiconductor chip 3 that has been cut out of the semiconductor wafer and an individual sheet that has been cut out of the sheet member 40 (hereinafter referred to as a “chip member”), are obtained. Then, each chip member is removed from its supporting sheet 60. In each chip member, the semiconductor chip 3 thereof includes the bump electrodes 31 and the individual sheet is laid over the surface, having the bump electrodes 31, of the semiconductor chip 3.

Next, the semiconductor chip 3 is bonded facedown onto the base member 2 with the sheet member 40 interposed between the base member 2 and the semiconductor chip 3. In this embodiment, the bonding process is carried out in the following manner using a flip-chip bonder 70 including a bonding head 71 and a stage 72 and having the capability of applying ultrasonic vibrations as shown in FIG. 3A. Note that in this embodiment, the flip-chip bonder 70 is configured such that the bonding head 71 thereof is able to apply ultrasonic vibrations. However, this is only an example and should not be construed as limiting. Alternatively, the flip-chip bonder 70 may have any other configuration as long as the flip-chip bonder 70 is able to apply ultrasonic vibrations to the conductor wiring 21 and the bump electrodes 31. For example, the stage 72 may have the capability of applying ultrasonic vibrations. Specific examples of the flip-chip bonder 70 include FCB3 manufactured by Panasonic Corporation. Also, in FIGS. 3A-3D and in the foregoing description, the encapsulation material 4 is supposed to be provided in advance on the semiconductor chip 3. However, this is only an example and should not be construed as limiting. Alternatively, with the base member 2 placed on the stage 72 and with the semiconductor chip 3 held by the bonding head 71, the sheet member 40 may be interposed between the base member 2 and the semiconductor chip 3, for example. In that case, the sheet member 40 may be interposed between the base member 2 and the semiconductor chip 3 by applying the encapsulation material 4 onto the base member 2, for example. Note that in the example described above, the encapsulation material is supposed to be formed in the sheet shape (i.e., as the sheet member 40). However, this is only an example and should not be construed as limiting. Alternatively, the encapsulation material may also be formed in a paste shape.

As shown in FIG. 3A, the base member 2 with the conductor wiring 21 is supported by the stage 72, and the semiconductor chip 3 is held by the bonding head 71 such that the bump electrodes 31 of the semiconductor chip 3 face the base member 2 supported on the stage 72. Meanwhile, the encapsulation material 4 is interposed between the base member 2 and the semiconductor chip 3. In this state, the bonding head 71 is moved toward the stage 72 as shown in FIG. 3B. This allows the semiconductor chip 3 to be placed in position over the base member 2 with the sheet member 40 interposed between them. At this time, the semiconductor chip 3 is aligned with the base member 2 such that the bump electrodes 31 of the semiconductor chip 3 are laid on top of the conductor wiring 21 of the base member 2.

In this case, ultrasonic vibrations are applied to the encapsulation material 4, the semiconductor chip 3, and the base member 2 via the bonding head 71 and the stage 72 while the encapsulation material 4, the semiconductor chip 3, and the base member 2 are being heated, thereby heating the solder bumps 32 and the encapsulation material 4. The heating temperature may be set appropriately according to either the composition of the solder bumps 32 and the composition of the encapsulation material 4 or the reaction start temperature of the encapsulation material 4. The heating temperature when the encapsulation material 4 is heated is preferably equal to or higher than the reaction start temperature minus 30° C. In that case, the advantages of this embodiment will be achieved significantly. The heating temperature is more preferably equal to or higher than the reaction start temperature minus 30° C. and equal to or lower than the reaction start temperature plus 10° C., and even more preferably falls within the range from 100° C. to 150° C.

The duration of applying the ultrasonic vibrations and the frequency of vibrations may be set appropriately. For example, the ultrasonic vibrations may be applied for a duration falling within the range from 0.1 seconds to 5.0 seconds and the frequency of vibrations may fall within the range from 10 kHz to 80 kHz.

Optionally, when ultrasonic vibrations are applied to the encapsulation material 4, the semiconductor chip 3, and the base member 2 via the bonding head 71 and the stage 72 while the encapsulation material 4, the semiconductor chip 3, and the base member 2 are being heated, load may be applied by the bonding head 71 onto the base member 2, the semiconductor chip 3, and the encapsulation material 4 on the stage 72. For example, the bonding head 71 may be configured to apply pressure toward the stage 72. This allows load to be applied by pressing the bonding head 71 against the semiconductor chip 3 with the encapsulation material 4 interposed between the base member 2 and the semiconductor chip 3. The condition for applying the load may be set appropriately in this case. For example, the load applied may fall within the range from 10 N to 200 N.

Also, the time it takes to have the semiconductor chip 3 bonded onto the base member 2 by applying ultrasonic vibrations to the encapsulation material 4 and the semiconductor chip 3 while heating the encapsulation material 4 and the semiconductor chip 3 preferably falls within the range from 0.5 seconds to 5 seconds from the start of heating, and more preferably falls within the range from 0.5 seconds to 2.0 seconds. If the time falls within this range, then the production time per chip is shorter than the one taken by the known thermal compression bonding method, for example, thus contributing to increasing the production efficiency.

As can be seen, applying ultrasonic vibrations to the solder bumps 32 and the encapsulation material 4 while heating the solder bumps 32 and the encapsulation material 4 with the encapsulation material 4 interposed between the base member 2 and the semiconductor chip 3 causes the solder bumps 32 to be melted, thus electrically connecting the bump electrodes 31 and the conductor wiring 21 together. In addition, causing the encapsulation material 4 to thermally cure after having been melted once allows the encapsulant 41 to be formed as shown in FIG. 3C. In this manner, the gap between the semiconductor chip 3 and the base member 2 is filled with the encapsulant 41.

Subsequently, as shown in FIG. 3D, the bonding head 71 is lifted upward and removed from the semiconductor chip 3.

Bonding the semiconductor chip 3 onto the base member 2 in this manner allows the semiconductor device 1 shown in FIG. 1A to be obtained. As can be seen, according to this embodiment, even when the temperature of the bonding head 71 is set at a relatively low temperature, the gap between the base member 2 and the semiconductor chip 3 may still be filled with the encapsulant 41. In addition, in the encapsulant 41 thus formed out of the encapsulation material 4, the number of residual voids has been reduced significantly as described above.

Optionally, after the semiconductor device 1 has been fabricated as described above, another semiconductor device 1 may be fabricated in succession using the same flip-chip bonder 70 again. In this embodiment, the encapsulation material 4 has a reaction start temperature equal to or lower than 160° C., exhibits peculiar viscosity behavior, and has low viscosity in a certain temperature range as described above. This facilitates setting the heating temperature at a relatively low temperature at the time of the bonding process, thereby allowing the temperature of the bonding head 71 to be set at a relatively low temperature. That is why even when a plurality of semiconductor devices 1 need to be fabricated in succession by repeating the same process over and over again, the time for cooling the bonding head 71 may be either eliminated or cut down significantly. This would improve the manufacturing efficiency of semiconductor devices 1.

In a variation of this embodiment, the semiconductor device 1 may also be implemented as a semiconductor device 1 with a multi-stage stack structure in which the encapsulants 41 and the semiconductor chips 3 are alternately stacked one on top of another in multiple stages on the base member 2 as shown in FIG. 1B. To fabricate a semiconductor device 1 with such a multi-stage stack structure, after the semiconductor chip 3 has been stacked over the base member 2 with the encapsulant 41 formed out of the encapsulation material 4 interposed between them as in the embodiment described above, another semiconductor chip 3 and another encapsulation material 4 may be heated and subjected to ultrasonic vibrations using the same flip-chip bonder 70 once again such that the latter (additional) semiconductor chip 3 is stacked over the former (already stacked) semiconductor chip 3 with an additional encapsulant 41 interposed between them. Repeating this process over and over again allows fabricating a semiconductor device 1 with such a multi-stage stack structure in which the encapsulants 41 and semiconductor chips 3 are alternately stacked one on top of another on the base member 2. In the exemplary semiconductor device 1 shown in FIG. 1B, the semiconductor chips 3 are stacked one on top of another in four stages. However, the number of the semiconductor chips 3 stacked does not have to be four but may be set as appropriate according to the application, intended use, or any other factor.

According to this variation of the exemplary embodiment, not only the heating temperature may be set at a relatively low temperature, but also the time for cooling the bonding head 71 of the flip-chip bonder 70 may be either eliminated or cut down significantly. This would improve the manufacturing efficiency even when a semiconductor device 1 with such a multi-stage stack structure is fabricated.

### EXAMPLES

### 1. Preparation of Examples 1-8 and Comparative Example 1

A liquid composition to make the encapsulation material was prepared in the following manner.

First, respective components shown in the “Composition” column of Table 1 were provided. Among these components, first, the acrylic compounds were weighed and stirred up and blended together with a disper. Subsequently, all components but the polyphenylene ether resin and the inorganic filler were added to, and blended with, this mixture of the acrylic compounds to prepare a first mixture solution. Meanwhile, a second mixture solution was prepared by dissolving the polyphenylene ether resin in a mixed solvent in which methyl ethyl ketone and toluene were mixed at a ratio of one to one. The first mixture solution and the inorganic filler were added to the second mixture solution, and these were stirred up with a disper and then blended together in a beads mill to have the inorganic filler dispersed. In this manner, a liquid composition was prepared. The concentration of the mixed solvent in the liquid composition was adjusted to fall within the range from 30% by mass to 50% by mass.

The details of the components shown in the “Composition” column of Table 1 are as follows. The weight reduction ratios of the acrylic compounds and the polyphenylene ether were calculated as follows. A thermogravimetric analyzer, such as model TG/DTA7300 manufactured by Seiko Instruments Inc., was used to heat the target from 25° C. to 300° C. at a temperature increase rate of 5° C./min within the air atmosphere and measure a variation in weight with the temperature. From a graph thus obtained, showing the relationship between the temperature and the variation in weight, the weight at the temperature (25° C.) before heating and the weight at 163° C. were read. The weight reduction ratios were calculated based on the difference in weight before and after the weight variation.
Acrylic compound 1: ethoxylated bisphenol A dimethacrylate, product number BPE-80N manufactured by Shin Nakamura Chemical Co., Ltd. (in Formula (III), R³ is a hydrogen atom, R⁴ is a dimethylmethylene group, and m+n=2.3), having a weight reduction ratio of 0.44%;
Acrylic compound 2: ethoxylated bisphenol A dimethacrylate, product number BPE-100N manufactured by Shin-Nakamura Chemical Co., Ltd., (in Formula (III), R³ is a hydrogen atom, R⁴ is a dimethylmethylene group, and m+n=2.6), having a weight reduction ratio of 0.22%;
Acrylic compound 3: ethoxylated bisphenol A dimethacrylate, product number BPE-200N manufactured by Shin Nakamura Chemical Co., Ltd., (in Formula (III), R³ is a hydrogen atom, R⁴ is a dimethylmethylene group, and m+n=4), having a weight reduction ratio of 0.14%;
Acrylic compound 4: ethoxylated bisphenol A dimethacrylate, product number BPE-500N manufactured by Shin Nakamura Chemical Co., Ltd., (in Formula (III), R³ is a hydrogen atom, R⁴ is a dimethylmethylene group, and m+n=10), having a weight reduction ratio of 0.25%;
Acrylic compound 5: ethoxylated bisphenol A dimethacrylate, product number BPE-1300N manufactured by Shin Nakamura Chemical Co., Ltd., (in Formula (III), R³ is a hydrogen atom, R⁴ is a dimethylmethylene group, and m+n=30) having a weight reduction ratio of 0.30%;
Acrylic compound 6: bisphenol A type epoxy acrylate, product number VR-77 manufactured by Showa High Polymer Co., Ltd., having a weight reduction ratio of 0.51%;
Acrylic compound 7: tricyclodecane dimethanol diacrylate, product number A-DCP manufactured by Shin Nakamura Chemical Co., Ltd., having a weight reduction ratio of 1.59%;
Acrylic compound 8: trimethylolpropane triacrylate, product number A-TMPT manufactured by Shin-Nakamura Chemical Co., Ltd., having a weight reduction ratio of 2.00%;
Polyphenylene ether resin: a modified polyphenylene ether resin, product number SA9000 manufactured by SABIC, having the structure expressed by Formula (3), in which X is a group (R is a methyl group) having the structure expressed by Formula (1), and having a weight reduction ratio of 0.36%;
Thermal radical polymerization initiator: dicumyl peroxide, product name Percumyl D manufactured by NOF CORPORATION;
Inorganic filler 1 (filler): silica powder, product number NMH-24D manufactured by Tokuyama Corporation, having a mean particle size of 0.24 μm;
Inorganic filler 2 (filler): silica particles, product number SO-C2 manufactured by Admatechs, having a mean particle size of 0.5 μm;
Modified polybutadiene: maleic acid modified polybutadiene, product name Ricobond 1756 manufactured by Cray Valley Co., Ltd.;
Thermoplastic resin: copolymer of methyl methacrylate and n-butyl methacrylate, product name DYNACOLL AC2740 manufactured by Evonik Japan;
Silane coupling agent: 3-glycidoxypropyltrimethoxysilane, product number KBM-403 manufactured by Shin-Etsu Chemical Co., Ltd.; and
Flux: sebacic acid.

2. Evaluation Tests

The encapsulation material was subjected to the following evaluation tests. The results of these evaluation tests are summarized in Table 1.

(1) Evaluation of Weight Reduction Ratio (Ratio of Volatile Components) of Composition

(1.1) Forming Sample (Laminate of Sheet Members)

A polyethylene terephthalate film was provided as a supporting sheet. This supporting sheet was coated with the liquid composition prepared as described for the section 1. to form, using a bar-coater, a film having a wet film thickness of 100 μm. Then, the film was heated under the condition including 130° C. and 15 minutes. In this manner, an encapsulation material (sheet member) was deposited to a thickness of 50 μm on the supporting sheet. A plurality of sheet members were stacked one on top of another to have a combined thickness of 200 μm to make a laminate. Then, the laminate was stripped from the supporting sheet. By cutting the laminate thus stripped, a sample having dimensions of 50 mm×50 mm in a plan view and a thickness of 200 μm was formed.

(1-2) Measuring Method

First, the weight of the sample (hereinafter referred to as a “sheet weight before drying”) at room temperature (of about 25° C.) was measured. Subsequently, the sample was loaded into a dryer set at 163° C. and dried for 15 minutes. When 15 minutes passed, the sample was unloaded from the dryer, loaded into a desiccator, and allowed to be cooled for 30 minutes. When 30 minutes passed, the sample was unloaded from the desiccator, and the weight of the sample (hereinafter referred to as a “sample weight after drying”) was measured.

Based on the weights thus measured, the weight reduction ratio (ratio of volatile components) of the composition at 163° C. was calculated by the following Equation (1):

Weight reduction rate (%) of composition=[(weight before drying)−(weight after drying)]/(weight before drying)×100 (1)

In addition, the weight reduction ratio at 130° C. was also measured in the same way. The weight reduction ratios measured at 163° C. and 130° C. for the respective compositions representing examples and a comparative example are summarized in the following Table 1.

(2) Measurement of Melt Viscosity and Evaluation of Reaction Start Temperature

The respective examples and comparative examples of the encapsulation material had the temperature dependence of their melt viscosity measured using a rheometer (model number AR2000ex) manufactured by TA Instruments Inc. under the condition including a temperature range of 100-300° C., a temperature increase rate of 60° C./min, and an angular velocity of 0.209 rad/s. In this manner, melt viscosity curves, each showing the relationship between the temperature and melt viscosity of an associated one of the encapsulation materials, were obtained. The reaction start temperature of each encapsulation material was obtained by reading the lowest melt viscosity from its melt viscosity curve and finding a temperature at a melt viscosity higher by 50 Pa·s than the lowest melt viscosity. The lowest melt viscosities, reaction start temperatures, and melt viscosity values at the reaction start temperatures are shown in their respective predetermined columns of Table 1.

(3) Evaluation of Glass Transition Temperature

A film of polyethylene terephthalate was provided as a supporting sheet. A film of a liquid resin composition prepared as described for the section 1. was deposited on the supporting sheet using a bar-coater so as to have a wet film thickness of 100 μm, and then was heated under the condition including 80° C. and 30 minutes. In this manner, a sheet member was formed to a thickness of 50 μm on the supporting sheet. A number of sheet members were stacked one on top of another, compressed with a vacuum laminator, heated by an oven under the condition including 150° C. and two hours to be cured, and then cut off, thereby making samples with dimensions 4 mm×40 mm in a plan view and a thickness of 800 μm. The glass transition temperature of this sample was measured with a thermal mechanical analyzer (TMA) (model number SS7100) manufactured by Seiko Instruments Inc. under the condition including a tensile force of 49 mN and a temperature program of 5° C./min within a temperature range from 30° C. to 300° C.

(4) Void Evaluation

A semiconductor device was fabricated in the following manner using an encapsulation material.

Walts TEG IP80 (10 mm×10 mm×300 μm) manufactured by WALTS Co., Ltd. was provided as a base member.

Walts TEG CC80 (7.3 mm×7.3 mm×100 μm) manufactured by WALTS Co., Ltd. was provided as a semiconductor wafer. The semiconductor wafer included 1,048 bump electrodes, each including a Cu pillar with a height of 30 μm and a solder bump stacked thereon and having a height of 15 μm and had a pitch of 80 μm between adjacent solder bumps.

A film of polyethylene terephthalate was provided as the supporting sheet. A film of a liquid composition prepared as described in the section 1. was deposited on the supporting sheet using a bar-coater so as to have a wet film thickness of 100 μm, and then was heated under the condition including 80° C. and 30 minutes. In this manner, a sheet member was formed to a thickness of 45 to 55 μm on the supporting sheet.

The sheet member was laid on top of the semiconductor wafer, the assembly was fixed onto a dicing frame, and the sheet member was diced, using a dicing saw (product name: DFD6341) manufactured by DISCO Corporation, with the silicon wafer still attached thereto, thereby cutting out a plurality of chip members, each including a semiconductor chip and an individual sheet with the encapsulation material having dimensions of 7.3 mm×7.3 mm×100 μm.

As a flip-chip bonder with the capability of applying ultrasonic vibrations, a flip-chip bonder with the model number FCB3 manufactured by Panasonic Corporation was used. With the stage of the flip-chip bonder heated, the base member was fixed onto the stage. The chip member was held by the bonding head of the flip-chip bonder and the bonding head was heated. In such a state, the bonding head was brought closer toward the stage and the individual sheet of the chip member was laid over the base member with the bump electrodes of the semiconductor chip aligned with the conductor wiring on the base member. The temperature of the stage was set at 145° C. and the temperature of the bonding head was set at 115° C. to make the heating temperature of the encapsulation material 130° C. In this state, ultrasonic vibrations were applied with the flip-chip bonder pressed against the semiconductor chip and with load placed on the semiconductor chip toward the base member. The load was placed under such a condition that a load of 10 N would be placed for 0.1 seconds since the load started to be placed, a load of 50 N would be placed at a point in time when 0.2 seconds passed since the start of placing the load, and a load of 50 N would be placed continuously from the point in time when 0.2 seconds passed since the start of placing the load through a point in time when 1.0 second passed since then. The ultrasonic vibrations started to be applied at a point in time when 0.5 seconds passed since the start of placing the load, were applied such that the output would reach 3 W at a point in time when 0.6 seconds passed since the start of placing the load, and had their output maintained at 3 W from the point in time when 0.6 seconds passed since the state of placing the load through a point in time when 1.0 second passed since then. When 1.0 second passed since the start of placing the load, the load stopped being placed and the bonding head was removed from the stage.

Subsequently, the encapsulation material interposed between the base member and the semiconductor chip was heated at a temperature of 150° C. for one hour to be cured completely, thus obtaining a semiconductor device under test. This semiconductor device was inspected using a scanning acoustic tomograph (SAT) to see if any voids were present in the encapsulant of the semiconductor device and count the number of voids detected within a range of 7.3 mm×7.3 mm. When no voids were detected from the encapsulant, the semiconductor device under test was graded “A.” When one to five voids were detected from the encapsulant, the semiconductor device under test was graded “B.” When more than five voids were detected from the encapsulant, the semiconductor device under test was graded “C.”

(5) Evaluation of Connectivity

Using the encapsulation material, a semiconductor device under test was fabricated by the same method as in the case of (3) void evaluation. The connectivity of the semiconductor device was evaluated in the following manner. Specifically, the semiconductor device was cut off, and a cross section thereof thus exposed was polished. The gap distance between the Cu pillar of the semiconductor chip and the conductor wiring of the base member via the solder bump as exposed on this cross section was measured. When the gap distance turned out to be less than 5 μm, the semiconductor device under test was graded “A.” When the gap distance fell within the range from 5 μm to less than 10 the semiconductor device under test was graded “B.” When the gap distance turned out to be equal to or greater than 10 μm, the semiconductor device under test was graded “C.”

(6) Evaluation of Peelability (Adhesion)

Using the encapsulation material, a semiconductor device under test was fabricated by the same method as in the case of (3) void evaluation. This semiconductor device was inspected using a scanning acoustic tomograph (SAT) to see if any peeling was observed at the interface between the cured product, the semiconductor chip, and the base member. When no peeling was observed, the semiconductor device under test was graded “A.” When any peeling was observed, the semiconductor device under test was graded “C.”

TABLE 1

| | | | | | | | | | | Comparative |
|---|---|---|---|---|---|---|---|---|---|---|
| | | Examples | | | | | | | | Example |
| | | 1 | 2 | 3 | 4 | 5 | 6 | 7 | 8 | 1 |
| Composition | Acrylic compound 1 | — | — | 14.9 | — | — | — | — | — | — |
| (parts by | Acrylic compound 2 | 14.9 | 14.9 | — | — | — | 16.1 | — | 9.9 | 2.4 |
| mass except | Acrylic compound 3 | — | — | — | 14.9 | — | — | — | — | — |
| phr) | Acrylic compound 4 | — | — | — | — | 14.9 | — | — | — | — |
| | Acrylic compound 5 | — | — | — | — | — | — | 14.9 | — | — |
| | Acrylic compound 6 | 1.2 | 1.2 | 1.2 | 1.2 | 1.2 | — | 1.2 | 1.2 | 1.2 |
| | Acrylic compound 7 | — | — | — | — | — | — | — | 5.0 | 12.2 |
| | Acrylic compound 8 | — | — | — | — | — | — | — | — | 0.3 |
| | Polyphenylene ether resin | 10.0 | 10.0 | 10.0 | 10.0 | 10.0 | 10.0 | 10.0 | 10.0 | 10.0 |
| | Thermal radical polymerization | 0.3 | 0.3 | 0.3 | 0.3 | 0.3 | 0.3 | 0.3 | 0.3 | 0.3 |
| | initiator [phr] | | | | | | | | | |
| | Inorganic filler 1 | 59.0 | — | 59.0 | 59.0 | 59.0 | 59.0 | 59.0 | 59.0 | 59.0 |
| | Inorganic filler 2 | — | 59.0 | — | — | — | — | — | — | — |
| | Modified polybutadiene | 3.5 | 3.5 | 3.5 | 3.5 | 3.5 | 3.5 | 3.5 | 3.5 | 3.5 |
| | Thermoplastic resin | 10.0 | 10.0 | 10.0 | 10.0 | 10.0 | 10.0 | 10.0 | 10.0 | 10.0 |
| | Silane coupling agent | 1.0 | 1.0 | 1.0 | 1.0 | 1.0 | 1.0 | 1.0 | 1.0 | 1.0 |
| | Flux [phr] | 0.4 | 0.4 | 0.4 | 0.4 | 0.4 | 0.4 | 0.4 | 0.4 | 0.4 |
| Evaluation | Weight reduction ratio (163° C.) [%] of | 0.26 | 0.26 | 0.22 | 0.24 | 0.25 | 0.25 | 0.22 | 0.34 | 1.74 |
| | composition | | | | | | | | | |
| | Weight reduction ratio (130° C.) [%] of | 0.11 | 0.11 | 0.11 | 0.09 | 0.11 | 0.11 | 0.11 | 0.17 | 0.44 |
| | composition | | | | | | | | | |
| | Reaction start temperature | 146 | 143 | 144 | 145 | 144 | 145 | 138 | 145 | 148 |
| | Melt viscosity [Pa · s] at reaction start | 273 | 75 | 284 | 219 | 200 | 260 | 330 | 278 | 143 |
| | temperature | | | | | | | | | |
| | Glass transition temperature Tg [° C.] | 136 | 136 | 137 | 137 | 136 | 138 | 125 | 142 | 166 |
| | Void | A | A | A | A | A | A | B | B | C |
| | Connectivity | A | A | A | A | A | A | A | A | A |
| | Sheet transparency | A | A | A | A | A | A | A | A | A |
| | Peelability | A | A | A | A | A | A | A | A | A |

### REFERENCE SIGNS LIST

1 Semiconductor Device
2 Base Member
21 Conductor Wiring
3 Semiconductor Chip
31 Bump Electrode
4 Encapsulation Material
40 Sheet Member
41 Encapsulant
42 Laminated Sheet

1. An encapsulation material for use to fill a gap between a base member and a semiconductor chip to be bonded onto the base member,
the encapsulation material having a reaction start temperature of 160° C. or less,
a total content of components volatilized from the encapsulation material when the encapsulation material is heated to at least one temperature falling within a range from 100° C. to 170° C. being 0.5% by mass or less of the entire encapsulation material.

2. The encapsulation material of claim 1, comprising:
an acrylic compound (A);
a polyphenylene ether resin (B) having a radical polymerizable substituent (b1);
a thermal radical polymerization initiator (C); and
an inorganic filler (D).

3. The encapsulation material of claim 2, wherein
the acrylic compound (A) contains a compound expressed by the following Formula (1): 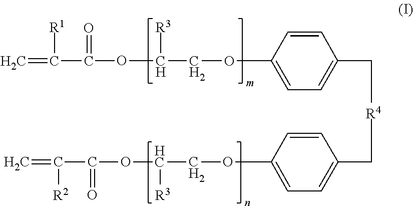
where R¹ and R² are each independently hydrogen or a methyl group, R³ represents hydrogen, a methyl group, or an ethyl group, and R⁴ represents a divalent organic group, and
each of m and n is a value falling within a range from 0 to 20 and an average value of m+n falls within a range from 2 to 30.

4. The encapsulation material of claim 1, wherein
the encapsulation material has a lowest melt viscosity of 300 Pa·s or less.

5. The encapsulation material of claim 1, wherein
a melt viscosity at the reaction start temperature is equal to or less than 350 Pa·s.

6. The encapsulation material of claim 1, wherein
the encapsulation material has a sheet shape.

7. The encapsulation material of claim 1, wherein
the base member includes conductor wiring,
the semiconductor chip includes a bump electrode, and
the encapsulation material is used to fill a gap between the base member and the semiconductor chip when the conductor wiring and the bump electrode are electrically connected together by bringing the conductor wiring and the bump electrode into contact with each other and by applying ultrasonic vibrations to the conductor wiring and the bump electrode while heating the conductor wiring and the bump electrode.

8. A laminated sheet comprising:
the encapsulation material of claim 6; and
a supporting sheet supporting the encapsulation material thereon.

9. A cured product obtained by thermally curing the encapsulation material of claim 1.

10. The cured product of claim 9, wherein
the cured product has a glass transition temperature equal to or higher than 130° C.

11. A semiconductor device comprising:
a base member;
a semiconductor chip bonded facedown onto the base member; and
an encapsulant filling a gap between the base member and the semiconductor chip,
the encapsulant being made of the cured product of claim 9.

12. A method for fabricating a semiconductor device, the method comprising:
providing a semiconductor chip including a bump electrode, with the encapsulation material of claim 1 interposed between the bump electrode and a surface having conductor wiring of a base member, such that the conductor wiring faces the bump electrode; and
curing the encapsulation material and electrically connecting the conductor wiring and the bump electrode together by applying ultrasonic vibrations to the encapsulation material while heating the encapsulation material.
